(19) United States
(12) Patent Application Publication
(10) Pub. No.: US 2010/0163828 A1
(43) Pub. Date: Jul. 1, 2010

(54) PHASE CHANGE MEMORY DEVICES AND METHODS FOR FABRICATING THE SAME

(75) Inventor: Li-Shu Tu, Taoyuan County (TW)

Correspondence Address: QUINTERO LAW OFFICE, PC, 615 Hampton Dr, Suite A202, Venice, CA, 90291, US

(73) Assignees: INDUSTRIAL TECHNOLOGY RESEARCH INSTITUTE, Hsinchu (TW); POWERCHIP SEMICONDUCTOR CORP., Hsin-Chu (TW); NANYA TECHNOLOGY CORPORATION, Taoyuan (TW); PROMOS TECHNOLOGIES INC., Hsinchu (TW); WINBOND ELECTRONICS CORP., Hsinchu (TW)

(21) Appl. No.: 12/464,014

(22) Filed: May 11, 2009

(30) Foreign Application Priority Data
Dec. 30, 2008 (TW) TW97151380

(51) Int. Cl. H01L 45/00; H01L 21/20

(52) U.S. Cl. 257/3; 438/478; 257/E45.002; 257/E21.09

(57) ABSTRACT

A phase change memory device is provided, including a semiconductor substrate with a first conductive semiconductor layer disposed thereover, wherein the first conductive semiconductor layer has a first conductivity type. A first dielectric layer is disposed over the semiconductor substrate. A second conductive semiconductor layer having a second conductivity type opposite to the first conductivity type is disposed in the first dielectric layer. A heating electrode is disposed in the first dielectric layer and formed over the second conductive semiconductor layer, wherein the heating electrode has a tapered cross section and includes metal silicide. A second dielectric layer is disposed over the first dielectric layer. A phase change material layer is disposed in the second dielectric layer. An electrode is disposed over the second dielectric layer, covering the phase change material layer.

### CROSS REFERENCE TO RELATED APPLICATIONS

This Application claims priority of Taiwan Patent Application No. 97151380, filed on Dec. 30, 2008, the entirety of which is incorporated by reference herein.

### BACKGROUND OF THE INVENTION

1. Field of the Invention

The invention relates to a memory device and more particularly to a phase change memory (PCM) device and a method for fabricating the same.

2. Description of the Related Art

Phase change memory devices are non-volatile, highly readable, and highly programmable memory devices, and require low driving voltage/current when compared to other memory devices. Technological development trends for phase change memory devices include, increasing cell density and reducing current density.

Phase change material in phase change memory devices has at least two solid phases, a crystalline state and an amorphous state. Transformation between the two phases can be achieved by changing the temperature of the phase change material. The phase change material exhibits different electrical characteristics depending on its state. For example, in an amorphous state, the material exhibits higher resistivity than in a crystalline state. Such phase change material may switch between numerous electrically detectable conditions of varying resistivity within a nanosecond time scale with the input of pico joules of energy. Chalcogenide, is a popular and widely used phase change material.

Since phase transformation of the phase change material is reversible, a bit status of a memory device can be distinguished by differences in resistivity of the phase change material.

FIG. 1 is a cross section view of a conventional phase change memory (PCM) cell. As shown in FIG. 1, an isolation structure 13 is located at a predetermined region of a semiconductor substrate 11 to thereby define an active region. A source region 17s and a drain region 17d are disposed apart in the active region. A gate 15, functioning as a word line, is disposed across the active region between the source region 17s and the drain region 17d. The gate 15, the source region 17s and the drain region 17d form a transistor. The semiconductor substrate 11 having the transistor thereon is covered with an insulating layer 19. An interconnection line 21 is disposed over the first insulating layer 19. The interconnection line 21 is electrically connected to the drain region 17d through a contact hole penetrating the first insulating layer 19. Another insulating layer 23 covers the interconnection line 21. A heating plug 25 is disposed in the insulating layers 19 and 23, electrically connected to the source region 17s. A patterned phase change material layer 27 and a top electrode 29 are sequentially stacked over the insulating layer 23, wherein a bottom surface of the phase change material layer pattern 27 is in contact with the heating plug 25. Another insulating layer 31 is disposed on the insulating layer 23. A bit line 33 is located on the insulating layer 31 and is in contact with the top electrode 29.

In a write mode, the transistor is turned on and a large current flows through the heating plug 25, thus heating up an interface between the phase change material layer pattern 27 and the heating plug 25, thereby transforming a portion 27a of the phase change material layer 27 into either the amorphous state or the crystalline state depending on the length of time and amount of current that flows through the heating plug 25.

Conventional phase change transistors as shown in FIG. 1, is the relatively large amount of current required to successfully change the state of the phase change material during a write operation. One solution to increase current density is to reduce a diameter D of the heating plug 25. There is still a limitation in the amount of reduction possible to the diameter D of the heating plug 25 because a photolithographic process determines the minimum diameter D. It is difficult to consistently produce a smaller diameter heating plug 25 due to limitations in the present photolithographic process. Moreover, the PCM cell illustrated in FIG. 1 is composed of the transistor and the phase change memory element stacked thereover. The formed PCM cell thus needs a greater size and it is difficult to consistently produce a PCM cell with reduced size.

### BRIEF SUMMARY OF THE INVENTION

An exemplary embodiment of a phase change memory device includes a semiconductor substrate. A first conductive semiconductor layer is disposed over the semiconductor substrate, wherein the first conductive semiconductor layer has a first conductivity type. A first dielectric layer is disposed over the semiconductor substrate, covering the first conductive semiconductor layer. A second conductive semiconductor layer is disposed in the first dielectric layer, and stacked over the first conductive semiconductor layer, wherein the second conductive semiconductor layer has a second conductivity type opposite to the first conductivity type. A heating electrode is disposed in the first dielectric layer and formed over the second conductive semiconductor layer, wherein the heating electrode has a tapered cross section and comprises metal silicide, and a top surface of the heating electrode is exposed by the first dielectric layer. A second dielectric layer is disposed over the first dielectric layer, covering the heating electrode. A phase change material layer is disposed in the second dielectric layer, covering the heating electrode. An electrode is disposed over the second dielectric layer, covering the phase change material layer.

Another exemplary embodiment of a phase change memory device includes a semiconductor substrate. A first conductive semiconductor layer is disposed over the semiconductor substrate, wherein the first conductive semiconductor layer has a first conductivity type. A first dielectric layer is disposed over the semiconductor substrate, covering the first conductive semiconductor layer. A second conductive semiconductor layer is disposed in the first dielectric layer and stacked over the first conductive semiconductor layer, wherein the second conductive semiconductor layer has a second conductivity type opposite to the first conductivity type. A heating electrode is disposed in the first dielectric layer and formed over the second conductive semiconductor layer, wherein the heating electrode has a rectangular cross section and comprises metal silicide, and a top surface of the heating electrode is exposed by the first dielectric layer. A second dielectric layer is disposed over the first dielectric layer, covering the heating electrode. A phase change material layer is disposed in the second dielectric layer, covering the heating electrode. An electrode is disposed over the second dielectric layer, covering the phase change material layer.

An exemplary embodiment of a method for fabricating a phase change memory device comprises providing a semiconductor substrate. A first conductive semiconductor layer is formed over the semiconductor substrate, wherein the first conductive semiconductor layer has a first conductivity type. A first dielectric layer is formed to cover the semiconductor substrate and the first conductive semiconductor layer. A second conductive semiconductor layer and a heating electrode are formed in the first dielectric layer, wherein the second conductive semiconductor layer and the heating electrode are sequentially stacked over the first conductive semiconductor layer, and the second conductive semiconductor layer has a second conductivity type different from the first conductivity type, and the heating electrode comprises metal silicide. A phase change material layer is formed to cover the heating electrode and portions of the first dielectric layer adjacent to the heating electrode. A second dielectric layer is formed to cover the first dielectric layer and the heating electrode and surrounding the phase change material layer. An electrode is formed over the second dielectric layer to cover the phase change material layer.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 is cross section of a conventional phase change memory cell structure;

FIGS. 2a-2f are cross sections showing a method for fabricating a phase change memory device according to an embodiment of the invention;

FIGS. 3a-3d are cross sections showing a method for fabricating a phase change memory device according to another embodiment of the invention; and

FIGS. 4a-4d are cross sections showing a method for fabricating a phase change memory device according to yet another embodiment of the invention.

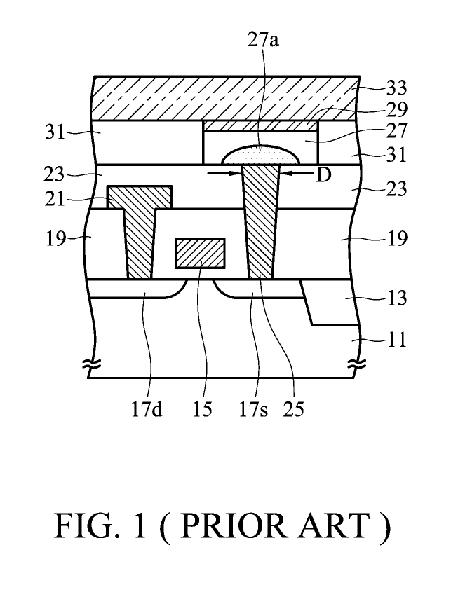

### DETAILED DESCRIPTION OF THE INVENTION

This description is made for the purpose of illustrating the general principles of the invention and should not be taken in a limiting sense. The scope of the invention is best determined by reference to the appended claims.

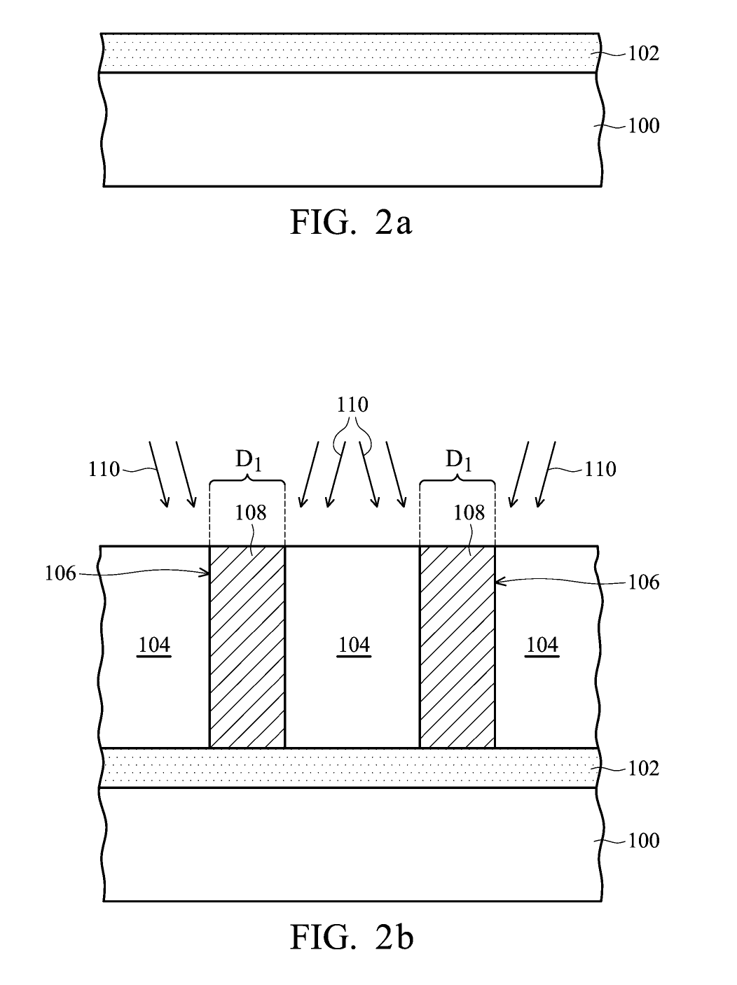

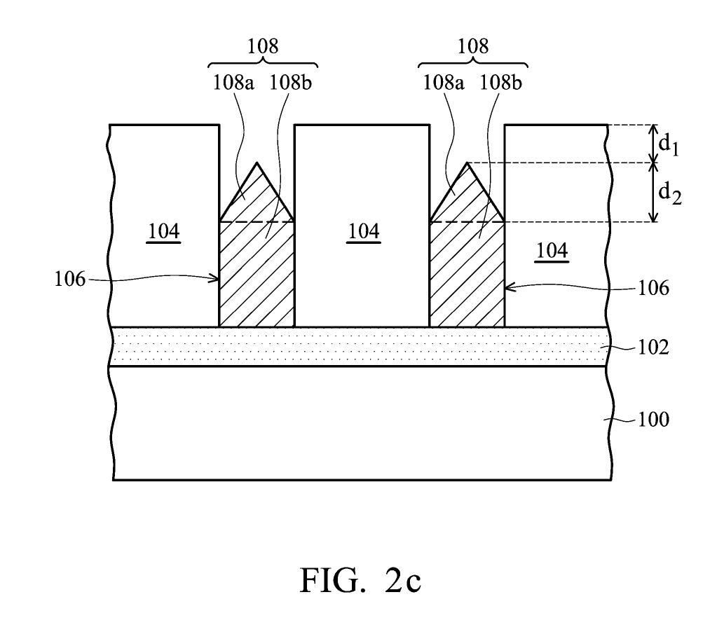

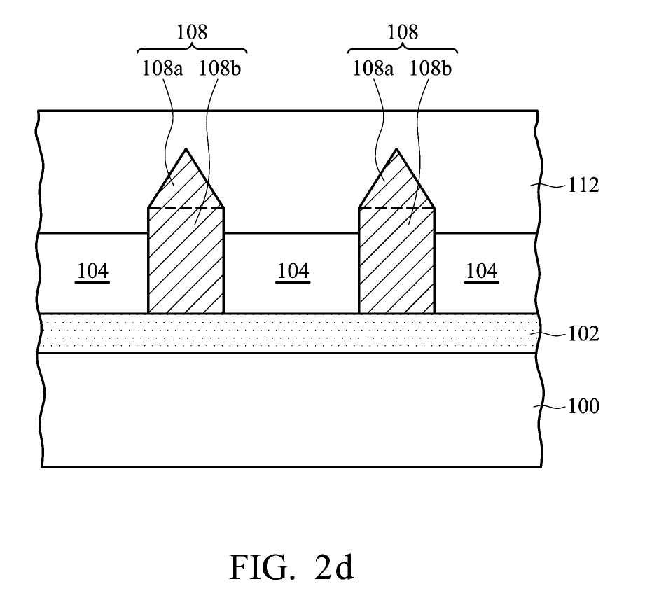

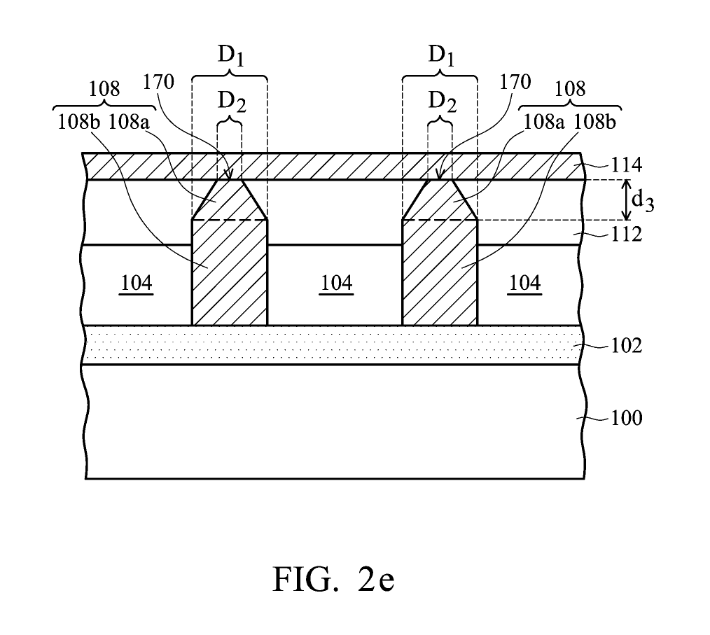

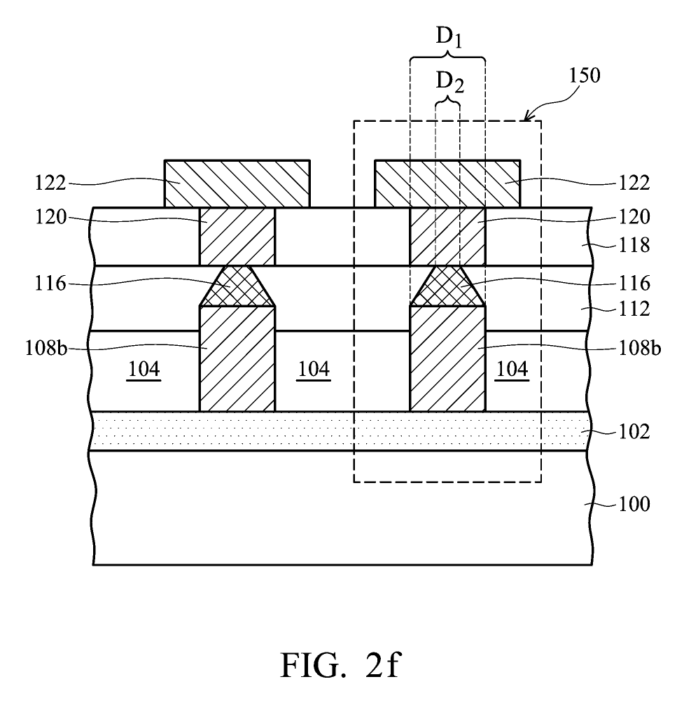

Embodiments of phase change memory devices and methods for fabricating the same are described as below with reference to FIGS. 2a-2f, 3a-3d, and 4a-4-d.

FIGS. 2a-2f are schematic diagrams showing fabrication steps of a method for fabricating a phase change memory device according to an exemplary embodiment.

Referring to FIG. 2a, a semiconductor substrate 100 is first provided, having a conductive semiconductor layer 102 of a first conductivity type formed thereover. In one embodiment, the semiconductor substrate 100 may comprise semiconductor materials such as silicon or silicon germanium, and the conductive semiconductor layer 102 may comprise amorphous silicon or polysilicon materials doped with n type dopants such as As or P ions. Herein, the conductive semiconductor layer 102 can be formed by, for example , a chemical vapor deposition process and is patterned as a patterned layer in parallel with a surface, as shown in FIG. 2a, partially covering the semiconductor layer 100.

Referring to FIG. 2b, a dielectric layer 104 is blanketly formed over the conductive semiconductor layer 102. The dielectric layer 104 may comprise dielectric materials such as borophosphosilicate glass (BPSG), silicon oxide, or spin-on glass (SOG), silicon nitride and may be formed by methods such as physical vapor deposition or spin-on coating. Thus, the dielectric layer 104 may have a substantially planar surface. A photolithography process and an etching process (both not shown) are then performed to define the dielectric layer 104, thereby forming a plurality of openings 106 in the dielectric layer 104. The openings 106 are formed through the dielectric layer 104 and expose a portion of the underlying conductive semiconductor layer 102. The openings 106 have a diameter DI of about 20-100 nm.

Next, a layer of conductive semiconductor material is blanketly deposited over the dielectric layer 104 and fills the openings 106. A planarization process (not shown) such as a chemical mechanical polishing process is then performed to remove the portion of the conducive semiconductor layer over the dielectric layer 104, thereby leaving a conductive semiconductor layer 108 in each of the openings 106. The conductive semiconductor layer 108 is disposed above the conductive semiconductor layer 102 and a top surface thereof is exposed by the dielectric layer 104. Herein the conductive semiconductor layer 108 has a second conductivity opposite to the first conductivity type of the conductive semiconductor layer 102 and may comprise amorphous silicon or polysilicon doped with p type dopants such as boron (B) ions. Herein, the dopants of the conductive semiconductor layer 108 can be in-situ doped during deposition of the semiconductor materials therein, or a layer of semiconductor material can be first deposited and dopants such as p type dopants can be then doped by an additional ion implanting process (not shown), thereby forming the conductive semiconductor materials of the conductive semiconductor layer 108.

Still referring to FIG. 2b, an ion implanting process 110 is then performed to implant ions such as Ge or O ions into portions of the conductive semiconductor layer 108. Herein, the ion implanting process 110 is a tilt implant process having an implant angel of about 5-85 degrees (an angle perpendicular to a top surface of the dielectric layer 104), and an implant concentration of about 10¹⁶/nm², and an implant energy of more than 50 Kev. After the ion implanting process 110, a region (not shown) implanted with the above described ions and another region (not shown) not implanted with the above described ions can be thus be defined in the conductive semiconductor layer 108.

Referring to FIG. 2c, an etching process (not shown) such as a wet etching process is then performed, using suitable etchants such as solutions containing HNO₃ or HF solutions to etch and remove the portion of the conductive semiconductor layer 108 implanted with the above described ions based on the etching characteristic differences between a layer doped with or without the Ge and O ions, thereby leaving a recessed conductive semiconductor layer 108 as illustrated in FIG. 2c.

As shown in FIG. 2c, the conductive semiconductor layer 108 left in each of the openings 106 is not doped with the above Ge or O ions and has a substantially stylus-shaped cross section. Herein, the conductive semiconductor layer 108 is substantially formed of a lower portion 108b with an upper portion 108a stacked thereover. The lower portion 108b is formed with a fixed diameter D₁ which is the same as that of the opening 106 and the upper portion 108a is formed with a non-fixed diameter increasing in size from bottom to top. The upper portion 108a of the conductive semiconductor layer 108 has a substantially triangular cross section and a tip thereof has a gap d₁ of about 0-100 nm from the top surface of the dielectric layer 104, and the upper portion 108a has a thickness d₂ of about 30-200 nm.

Referring to FIG. 2d, an etching process (not shown) is performed to partially remove the dielectric layer 104 and expose portions of the conductive semiconductor layer 108. After the etching process, the upper portion 108a and portions of the lower portion 108b of the conductive semiconductor layer 108 are exposed by the dielectric layer 104. Next, a dielectric layer 112 is blanketly formed over the dielectric layer 104 and the conductive semiconductor layer 108 to cover the above layers. Materials of the dielectric layer 112 can be, for example, undoped silicon glass (USG) formed by a chemical vapor deposition method.

Referring to FIG. 2e, a planarization process (not shown) such as a chemical mechanical polishing process is performed to remove the portion of dielectric layer 112 above the upper portion 108a of the conductive semiconductor layer 108. Portions of the upper portion 108a of the conductive semiconductor layer 108 are also removed in the planarization process, thereby leveling off the tip portion of the upper portion 108a of the conductive semiconductor layer 108 and providing a substantially planar top surface. Herein, a top surface 170 of the upper portion 108a of the conductive semiconductor layer 108 has a diameter D₂ of about 10-90 nm, and the upper portion 108a of the conductive semiconductor layer 108 has a thickness d₃ of about 10-100 nm. Next, a metal layer 114 is blanketly formed over the dielectric layer 112 to cover the conductive semiconductor layer 108 and a top surface of the upper portion 108a of the conductive semiconductor layer 108. The metal layer 114 may comprise noble metal materials such as Co, or Ni, or refractory metal materials such as Ti, V, Cr, Zr, Mo, Hf, Ta, or W.

Referring to FIG. 2f, an annealing process (not shown) is performed to cause metal silicidation between the metal layer 114 and the upper portion 108a of the conductive semiconductor layer 108 contacting therewith, thereby converting the doped semiconductor materials in the upper portion 108a of the conductive semiconductor layer 108 into the metal silicide and thus reducing a contact resistance thereof. Therefore, after the annealing process, the upper portion 108a of the conductive semiconductor layer 108 is converting into a metal silicide layer 116. Herein, the metal silicide layer 116 functions as a heating electrode for a phase change memory device.

Referring to FIG. 2f, the unreacted portions (not shown) of the metal layer 114 are then removed and a layer of phase change materials (not shown) is then formed over the dielectric layer 112, having a thickness of about 10-200 nm, to cover the dielectric layer 112 and the metal silicide layer 116. Herein, the phase change material can be, for example, chalcogenide materials such as Ge—Sb—Te trinary chalcogenide compound or doped chalcogenide compound, and can be formed by, for example, physical or chemical deposition methods. Next, a photolithography process and an etching process (both not shown) are performed to pattern the layer of phase change material, thereby forming a phase change material layer 120 over the metal silicide layer 116 and portions of the dielectric layer 112 adjacent to the metal silicide layer 116. Herein, the phase change material layer 120 covers a top surface the metal silicide layer 116 thereunder.

Next, a layer of dielectric material layer is blanketly formed over the semiconductor substrate 100 to cover the phase change material layers 120 and the dielectric layer 112. Next, a planarization process (not shown) is performed to remove the portion of the layer of dielectric material above the phase change material layer 120, thereby forming a dielectric layer 118. The dielectric layer 118 surrounds the phase change material layer 120. Herein, the dielectric layer 118 may comprise silicon oxide formed by, for example, chemical vapor deposition.

Next, a layer of conductive material, such as Ti, TiN, TiW, W, Al, TaN formed by methods such as chemical vapor deposition, is blanketly formed over the dielectric layer 118. Next, a photolithography process (not shown) is performed to pattern and partially remove portions of the layer of conductive materials, thereby forming a plurality of electrodes 122 isolated from each other. Herein, as shown in FIG. 2f, the electrodes 122 extend along a direction perpendicular to the surface, as shown in FIG. 2f and are respectively disposed over a portion of the dielectric layer 118 to contact the phase change material layer 120 thereunder.

As shown in FIG. 2f, the phase change memory device of the invention may comprise a memory cell array made of a plurality of phase change memory cells 150 disposed over the substrate 100. A semiconductor substrate 100 is provided, and has a first conductive semiconductor layer (e.g. the conductive semiconductor layer 102) disposed thereover, and the first conductive semiconductor layer has a first conductivity type. A first dielectric layer (composed of the dielectric layer 104 and 112) is disposed over the semiconductor substrate, covering the first conductive semiconductor layer. A second conductive semiconductor layer (e.g. the conductive semiconductor layer 108b) is disposed in the first dielectric layer, stacked over the first conductive semiconductor layer, wherein the second conductive semiconductor layer has a second conductivity type opposite to the first conductivity type. A heating electrode (the metal silicide layer 116) is disposed in the first dielectric layer and formed over the second conductive semiconductor layer, wherein the heating electrode comprises metal silicide and a top surface of the heating electrode is exposed by the first dielectric layer. A second dielectric layer (e.g. the dielectric layer 118) is disposed over the first dielectric layer, covering the heating electrode. A phase change material layer (e.g. the phase change material layer 120) is disposed in the second dielectric layer, covering the heating electrode. An electrode (e.g. the electrode 122) is disposed over the second dielectric layer, covering the phase change material layer.

In this embodiment, the heating electrode is formed with a diameter smaller than that of the phase change material layer 112 and has a non-fixed diameter of about 10-90 nm. As shown in FIG. 2f, the heating electrode is formed with a tapered cross section. The conductive semiconductor layer 102 and the conductive semiconductor layer 108b provide an n-p junction and thus functions as an active device for connecting with the memory element.

According to the embodiments of the invention, the phase change memory device has the following advantages:

1. Because the phase change material layer is disposed directly over the active device therein, an area for disposing the unit memory cell can be reduced, thus, improving memory cell density.

2. Because a metal silicide layer 116 with a tapered cross section is provided under the phase change material layer as a heating electrode and a contact area therebetween is reduced.

3. In addition, because a metal silicide layer 116 with a tapered cross section is provided under the phase change material layer as the heating electrode, write currents and reset currents can be further reduced, thus allowing for further reduction of the cell size.

4. According to illustrations in FIGS. 2a-2f, since the metal silicide layer 116 which functions as a heating electrode is formed with a tapered cross section by a non-photolithographical method. Thus, adjustments and size reduction of the heating electrode will not be limited by the photolithography process as that mentioned in the conventional process.

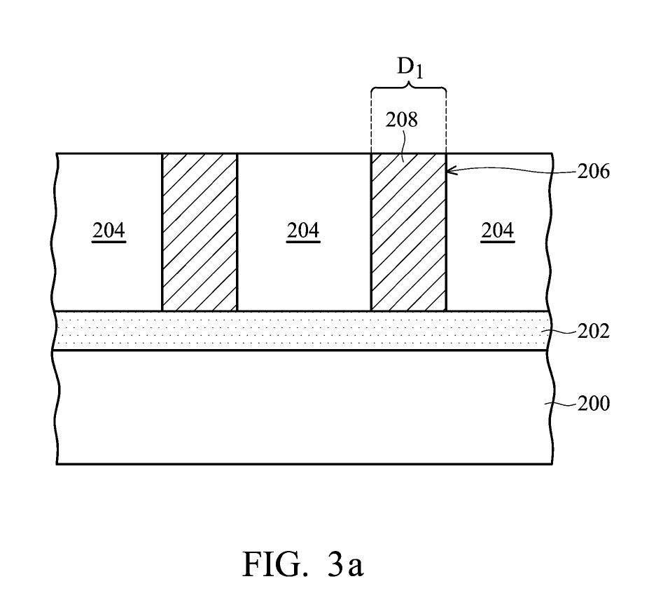

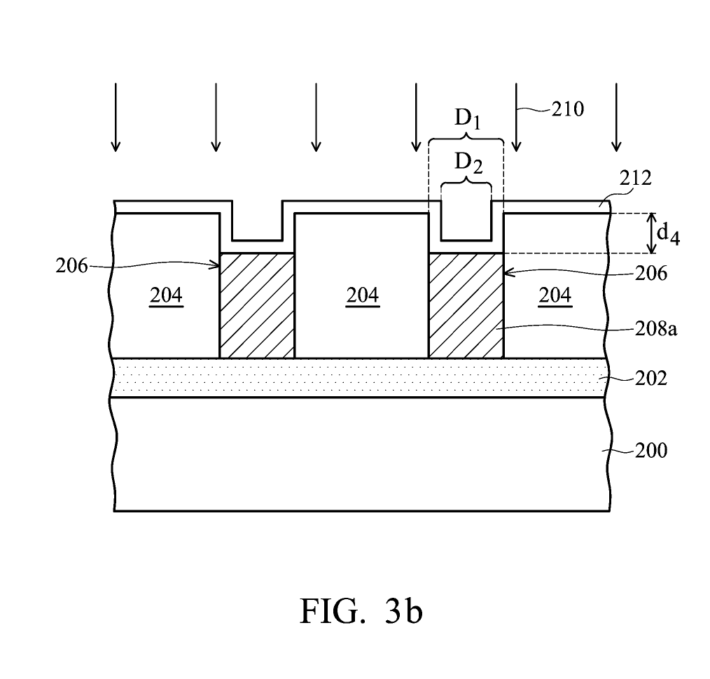

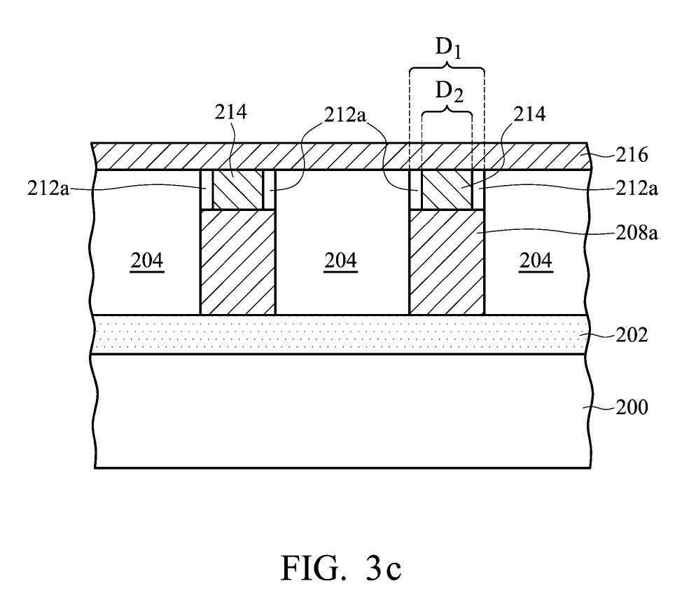

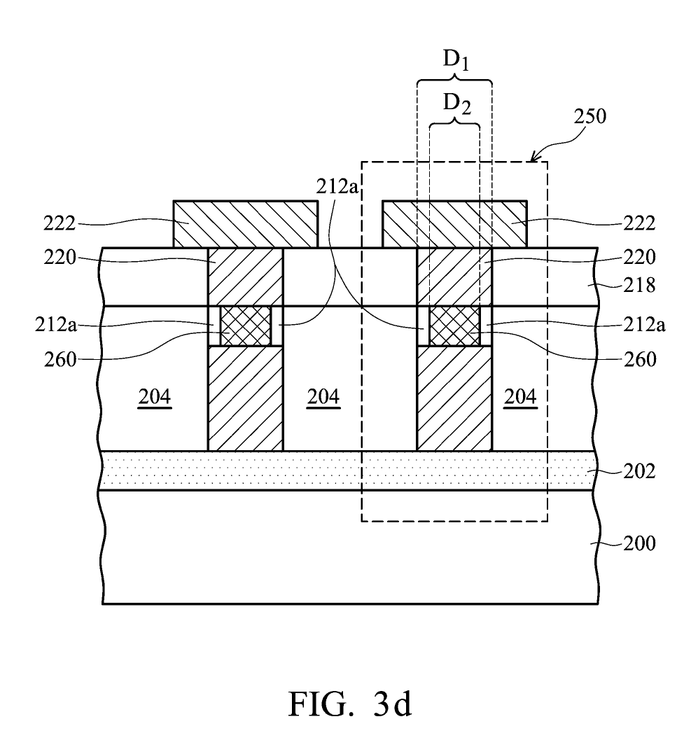

FIGS. 3a-3d are schematic diagrams showing fabrication steps of a method for manufacturing a phase change memory device according to another exemplary embodiment.

Referring to FIG. 3a, a semiconductor substrate 200 is first provided with a conductive semiconductor layer 202 of a first conductivity type formed thereover. In one embodiment, the semiconductor substrate 200 may comprise semiconductor materials such as silicon or silicon germanium and the conductive semiconductor layer 202 may comprise amorphous silicon or polysilicon materials doped with n type dopants such as As or P. Herein, the conductive semiconductor layer 202 can be formed by, for example , a chemical vapor deposition process and is patterned as a patterned layer in parallel with a surface, as shown in FIG. 3a, partially covering the semiconductor layer 200.

A dielectric layer 204 is then blanketly formed over the conductive semiconductor layer 202. The dielectric layer 204 may comprise dielectric materials such as borophosphosilicate glass (BPSG), silicon oxide, spin-on glass (SOG), or silicon nitride and may be formed by methods such as physical vapor deposition or spin-on deposition. Thus, the dielectric layer 204 may have a substantially planar surface. A photolithography process and an etching process (both not shown) are then performed to define the dielectric layer 204, thereby forming a plurality of openings 206 in the dielectric layer 204. The openings 206 form through the dielectric layer 204 and expose a portion of the underlying conductive semiconductor layer 202, respectively, having a diameter D₁ of about 20-100 nm.

Still referring to FIG. 3a, a layer of conductive semiconductor material is then blanketly deposited over the dielectric layer 204 and fills the openings 206. A planarization process (not shown) such as a chemical mechanical polishing process is then performed to remove the portion of the conducive semiconductor material above the dielectric layer 204, thereby leaving a conductive semiconductor layer 208 in each of the openings 206. The conductive semiconductor layer 208 is disposed above the conductive semiconductor layer 202 and a top surface thereof is exposed by the dielectric layer 204. Herein, the conductive semiconductor layer 208 has a second conductivity opposite to the first conductivity type of the conductive semiconductor layer 202 and may comprise amorphous silicon or polysilicon layer doped with p type dopants such as boron (B) ions. Herein, dopants of the conductive semiconductor layer 208 can be in-situ doped during deposition of the semiconductor materials therein, or a layer of semiconductor material can be first deposited and dopants such as p type dopants can be then doped by an additional ion implanting process (not shown), thereby forming the conductive semiconductor materials of the conductive semiconductor layer 208.

Referring to FIG. 3b, an etching process 210, for example a wet etching process using suitable etchants such as solutions containing HCl, HBr, H₃PO₄, HNO₃ or KOH is performed to etch and remove portions of the conductive semiconductor layer 208 in the openings 206, thereby forming the recessed conductive semiconductor layer 208a as illustrated in FIG. 3b. Herein, the conductive semiconductor layer 208a has a fixed diameter D1 which is the same as that of the opening 206 and is spaced from a top surface of the dielectric layer 204 with a distance d₄ of about 30-200 nm.

Next, a dielectric layer 212 with a thickness of about 5-90 nm is conformably formed over the dielectric layer 204. The dielectric layer 212 formed in the opening 206 covers sidewalls of the dielectric layer 204 and a top surface of the conductive semiconductor layer 208a exposed by the opening 206. Materials of the dielectric layer 212 can be, for example, silicon oxide formed by a chemical vapor deposition method.

Referring to FIG. 3c, an etching process (not shown) is then performed to etch back the dielectric layer 212, thereby forming a liner layer 212a on sidewalls of the dielectric layer 204 in the opening 206. The liner layers 212a partially expose the conductive semiconductor layer 208a thereunder. Next, a layer of conductive semiconductor layer material (not shown) is then blanketly deposited over the dielectric layer 204 and fills the opening 206. Next, a planarization process (not shown) such as a chemical mechanical polishing process is performed to remove the portion of conductive semiconductor materials above the dielectric layer 204, thereby forming another conductive semiconductor layer 214 in the opening 206 and a top surface of the conductive semiconductor layer 214 is exposed, having a diameter D₂ of about 10-90 nm. Herein, the conductive semiconductor layer 214 and the underlying conductive semiconductor layer 208a have the second conductivity type opposite to the first conductivity type of the conductive semiconductor layer 202. The conductive semiconductor layer 214 also has a second conductivity opposite to the first conductivity type of the conductive semiconductor layer 202 and may comprise amorphous silicon or polysilicon doped with p type dopants such as boron (B) ions. Herein, dopants of the conductive semiconductor layer 214 can be in-situ doped during deposition of the semiconductor materials therein, or a layer of semiconductor material can be first deposited and dopants such as p type dopants can be then doped by an additional ion implanting process (not shown), thereby forming the conductive semiconductor materials of the conductive semiconductor layer 214.

Next, a metal layer 216 is blanketly formed over the dielectric layer 204 and covers the conductive semiconductor layer 214 and the liner layer 212a. The metal layer 216 may comprise noble metal materials such as Co or Ni, or refractory metal materials such as Ti, V, Cr, Zr, Mo, Hf, Ta, or W.

Referring to FIG. 3d, an annealing process (not shown) is performed to cause metal silicidation between the metal layer 216 and the conductive semiconductor layer 214, thereby converting the doped semiconductor materials therein into metal silicide and reducing a contact resistance thereof. Thus, after the annealing process, the conductive semiconductor layer 214 is converted into a metal silicide layer 260. Herein, the metal silicide layer 260 functions as a heating electrode for a phase change memory device.

Referring to FIG. 3d, the unreacted portions (not shown) of the metal layer 216 are then removed and a layer of phase change materials (not shown) is then formed over the dielectric layer 204, having a thickness of about 10-200 nm to cover the dielectric layer 204, the liner layer 212a and the metal silicide layer 260. Herein, the phase change material can be, for example, chalcogenide materials such as Ge—Sb—Te trinary chalcogenide compound or doped chalcogenide compound, and can be formed by, for example, physical or chemical deposition methods. Next, a photolithography process and an etching process (both not shown) are performed to pattern the phase change material layer, thereby forming a phase change material layer 220 over the metal silicide layer 260 and portions of the dielectric layer 204 adjacent to the metal silicide layer 260. Herein, the phase change material layer 220 covers a top surface of the metal silicide layer 260 thereunder.

Next, a dielectric material layer is blanketly formed over the semiconductor substrate 200 to cover the phase change material layers 220 and the dielectric layer 204. Next, a planarization process (not shown) is performed to remove the portion of the dielectric materials above the phase change material layers, thereby forming a dielectric layer 218. The dielectric layer 218 surrounds the phase change material layers 220. Herein, the dielectric layer 218 may comprise silicon oxide formed by, for example, chemical vapor deposition.

Next, a layer of conductive material, such as Ti, TiN, TiW, W, Al, or TaN, is blanketly formed over the dielectric layer 218 by methods such as chemical vapor deposition. Next, a photolithography process (not shown) is performed to pattern and partially remove portions of the layer of conductive materials, thereby forming a plurality of electrodes 222 isolated from each other. Herein, as shown in FIG. 3d, the electrodes 122 extend along a direction perpendicular to the surface, and are respectively disposed over a portion of the dielectric layer 218 to contact the phase change material layer 220 thereunder.

As shown in FIG. 3d, the phase change memory device of the invention may comprise a memory cell array made of a plurality of phase change memory cells 250 disposed over the substrate 200. A semiconductor substrate 200 is provided with a first conductive semiconductor layer (e.g. the conductive semiconductor layer 202) disposed thereover, and the first conductive semiconductor layer has a first conductivity type. A first dielectric layer (composed of the dielectric layer 204) is disposed over the semiconductor substrate, covering the first conductive semiconductor layer. A second conductive semiconductor layer (e.g. the conductive semiconductor layer 208b) is disposed in the first dielectric layer, stacked over the first conductive semiconductor layer, wherein the second conductive semiconductor layer has a second conductivity type opposite to the first conductivity type. A heating electrode (the metal silicide layer 260) is disposed in the first dielectric layer and formed over the second conductive semiconductor layer, wherein the heating electrode comprises metal silicide and a top surface of the heating electrode is exposed by the first dielectric layer. A second dielectric layer (e.g. the dielectric layer 218) is disposed over the first dielectric layer, covering the heating electrode. A phase change material layer (e.g. the phase change material layer 220) is disposed in the second dielectric layer, covering the heating electrode. An electrode (e.g. the electrode 222) is disposed over the second dielectric layer, covering the phase change material layer.

In this embodiment, the metal silicide layer 260 functioning as the heating electrode is formed with a diameter smaller than that of the phase change material layer 212 and has a fixed diameter of about 10-90 nm. A liner layer 212a is disposed between the metal silicide layer 260 and the dielectric layer 204. As shown in FIG. 3d, the heating electrode is formed with a rectangular cross section. The conductive semiconductor layer 202 and the conductive semiconductor layer 208a provide an n-p junction and thus functions as an active device for connecting the memory element.

According to above embodiments the phase change material layer is disposed directly over the active device therein, an area for disposing the unit memory cell can be reduced, thus, improving memory cell density.

A metal silicide layer 260 with a rectangular cross section is provided under the phase change material layer as a heating electrode and a contact area therebetween is reduced.

A metal silicide layer 260 with a rectangular cross section is provided under the phase change material layer as the heating electrode, write currents and reset currents can be further reduced, thus allowing for further reduction of the cell size.

4. According to illustrations in FIGS. 3a-3c, since the metal silicide layer 260 which functions as a heating electrode is formed with a rectangular cross section by a non-photolithographical method. Thus, adjustments and size reduction of the heating electrode will not be limited by the photolithography process as that mentioned in the conventional process.

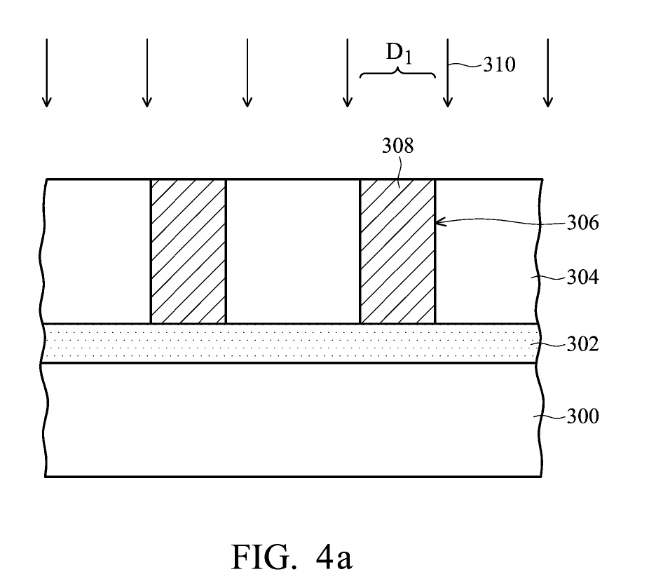

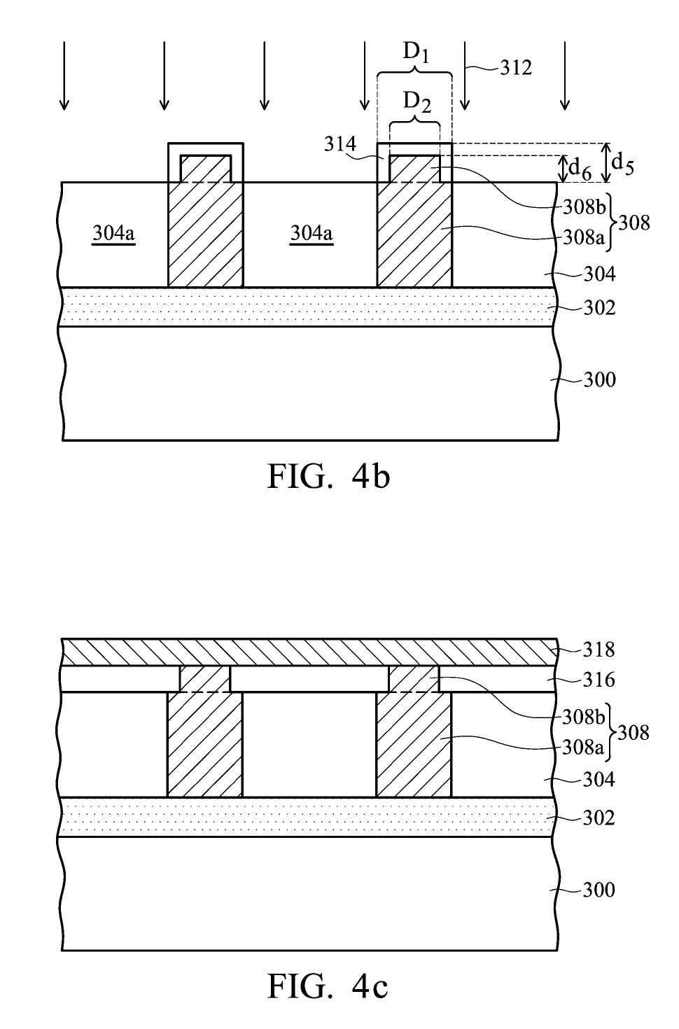

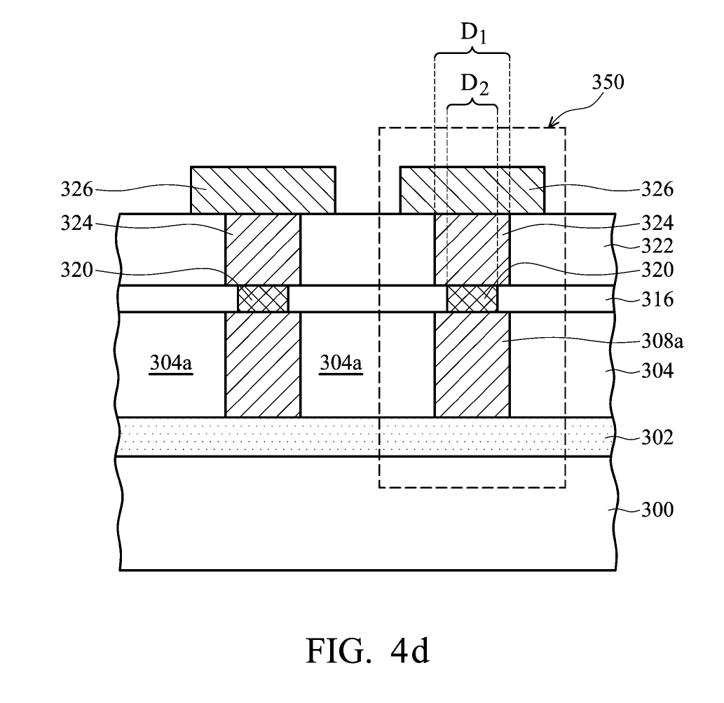

FIGS. 4a-4d are schematic diagrams showing fabrication steps of a method for manufacturing a phase change memory device according to yet another exemplary embodiment.

Referring to FIG. 4a, a semiconductor substrate 300 is first provided with a conductive semiconductor layer 302 of a first conductivity type formed thereover. In one embodiment, the semiconductor substrate 300 may comprise semiconductor materials such as silicn or silicon germanium and the conductive semiconductor layer 302 may comprise amorphous silicon or polysilicon materials doped with n type dopants such as As or P. Herein, the conductive semiconductor layer 302 can be formed by, for example , a chemical vapor deposition process and is patterned as a patterned layer in parallel with a surface, as shown in FIG. 4a, partially covering the semiconductor layer 300.

A dielectric layer 304 is then blanketly formed over the conductive semiconductor layer 302. The dielectric layer 304 may comprise dielectric materials such as borophosphosilicate glass (BPSG), silicon oxide, spin-on glass (SOG), or silicon nitride and may be formed by methods such as physical vapor deposition or spin-on deposition. Thus, the dielectric layer 304 may have a substantially planar surface. A photolithography process and an etching process (both not shown) are then performed to define the dielectric layer 304, thereby forming a plurality of openings 306 in the dielectric layer 304. The openings 306 are formed through the dielectric layer 304 and expose a portion of the underlying conductive semiconductor layer 302, respectively, having a diameter D₁ of about 20-100 nm.

Still referring to FIG. 4a, a layer of conductive semiconductor material is then blanketly deposited over the dielectric layer 304 and fills the openings 306. A planarization process (not shown) such as a chemical mechanical polishing process is then performed to remove the portion of the conducive semiconductor material above the dielectric layer 304, thereby leaving a conductive semiconductor layer 308 in each of the openings 306. The conductive semiconductor layer 308 is disposed above the conductive semiconductor layer 302 and a top surface thereof is exposed by the dielectric layer 304. Herein, the conductive semiconductor layer 308 has a second conductivity opposite to the first conductivity type of the conductive semiconductor layer 302 and may comprise amorphous silicon or polysilicon layer doped with p type dopants such as boron (B) ions. Herein, dopants of the conductive semiconductor layer 308 can be in-situ doped during deposition of the semiconductor materials therein, or a layer of semiconductor material can be first deposited and dopants such as p type dopants can be then doped by an additional ion implanting process (not shown), thereby forming the conductive semiconductor materials of the conductive semiconductor layer 308.

Still Referring to FIG. 4a, an etching process 310, for example an wet etching process using suitable etchants such as solutions containing HNO₃ or HF is performed to etch and remove portions of a portion of the dielectric layer 304 of a thickness d₅ of about 30-200 nm (See FIG. 4b), thereby exposing portions of the conductive semiconductor layer 308 and leaving the conductive semiconductor layer 308 protruding over the dielectric layer 304 as shown in FIG. 4b, having an upper portion 308b protruding over a top surface of the dielectric layer 304 and a lower portion 308a embedded in the dielectric layer 304. Next, a thermal oxidation process 312 is performed to oxidize portions of the upper portion 308a of the conductive semiconductor layer 308 into an oxide layer 314. The thermal oxidation process 312 can be, for example, a thermal oxidation process or a natural oxidization process. Thus, the low portion 308a of the conductive semiconductor layer 308 has a diameter the same with the diameter D₁ of the opening 306. The upper portion 308b of the conductive semiconductor layer 308 is covered by the oxide layer 314 protruding over the dielectric layer 304, having a diameter D₂ of about 10-90 nm. Herein, the upper portion 308a of the conductive semiconductor layer 308 is apart from the top surface of the dielectric layer 304 with a distance d₆ of about 30-200 nm.

Referring to FIG. 4c, an etching process (not shown) is performed to remove the oxide layer 314 and expose the upper portion 308b of the conductive semiconductor layer 308. Next, a layer of dielectric material is blanketly deposited over the dielectric layer 304 and a planarization process (not shown) such as chemical mechanical polishing process is performed to remove the dielectric material above the top surface of the top portion of the conductive semiconductor layer 308, thereby forming the dielectric layer 316 surrounding the conductive semiconductor layer 308 and exposing a top surface of the upper portion 308b of the conductive semiconductor layer 308.

Next, a metal layer 318 is blanketly formed over the dielectric layer 316 and covers the conductive semiconductor layer 308. The metal layer 318 may comprise noble metal materials such as Co or Ni, or refractory metal materials such as Ti, V, Cr, Zr, Mo, Hf, Ta, or W.

Referring to FIG. 4d, an annealing process (not shown) is performed to cause metal silicidation between the metal layer 318 and the upper portion 308b of the conductive semiconductor layer 214 contacting therewith, thereby converting the doped semiconductor materials in the upper portion 308b into metal silicide and reducing a contact resistance thereof. Thus, after the annealing process, the conductive semiconductor layer 308 is converted into a metal silicide layer 320. Herein, the metal silicide layer 320 functions as a heating electrode for a phase change memory device.

Referring to FIG. 4d, the unreacted metal layer 318 is then removed and a layer of phase change materials (not shown) is then formed over the dielectric layer 316, having a thickness of about 10-200 nm to cover the dielectric layer 316 and the metal silicide layer 320. Herein, the phase change material can be, for example, chalcogenide materials such as Ge—Sb—Te trinary chalcogenide compound or doped chalcogenide compound, and can be formed by, for example, physical or chemical deposition methods. Next, a photolithography process and an etching process (both not shown) are performed to the phase change material layer, thereby forming a phase change material layer 324 over the metal silicide layer 320 and portions of the dielectric layer 316 adjacent to the metal silicide layer 320. Herein, the phase change material layer 324 covers a top surface of the metal silicide layer 320 thereunder.

Next, a dielectric material layer is blanketly formed over the semiconductor substrate 300 to cover the phase change material layer 324 and the dielectric layer 316. Next, a planarization process (not shown) is performed to remove the portion of the dielectric materials above the phase change material layer 324, thereby forming a dielectric layer 322. The dielectric layer 322 surrounds the phase change material layer 324. Herein, the dielectric layer 324 may comprise silicon oxide formed by, for example, chemical vapor deposition.

Next, a layer of conductive material, such as conductive materials such as Ti, TiN, TiW, W, Al, or TaN formed by methods such as chemical vapor deposition, is blanketly formed over the dielectric layer 324. Next, a photolithography process (not shown) is performed to pattern and partially remove portions of the layer of conductive materials, thereby forming a plurality of electrodes 326 isolated from each other. Herein, as shown in FIG. 4d, the electrodes 326 extend along a direction perpendicular to the surface, as shown in FIG. 4d and are respectively disposed over a portion of the dielectric layer 322 to contact the phase change material layer 324 thereunder.

As shown in FIG. 4d, the phase change memory device of the invention may comprise a memory cell array made of a plurality of phase change memory cells 350 disposed over the substrate 300. A semiconductor substrate 300 is provided with a first conductive semiconductor layer (e.g. the conductive semiconductor layer 302) disposed thereover, and the first conductive semiconductor layer has a first conductivity type. A first dielectric layer (composed of the dielectric layers 304 and 316) is disposed over the semiconductor substrate, covering the first conductive semiconductor layer. A second conductive semiconductor layer (e.g. the conductive semiconductor layer 308a) is disposed in the first dielectric layer, stacked over the first conductive semiconductor layer, wherein the second conductive semiconductor layer has a second conductivity type opposite to the first conductivity type. A heating electrode (the metal silicide layer 320) is disposed in the first dielectric layer and formed over the second conductive semiconductor layer, wherein the heating electrode comprises metal silicide and a top surface of the heating electrode is exposed by the first dielectric layer. A second dielectric layer (e.g. the dielectric layer 322) is disposed over the first dielectric layer, covering the heating electrode. A phase change material layer (e.g. the phase change material layer 324) is disposed in the second dielectric layer, covering the heating electrode. An electrode (e.g. the electrode 326) is disposed over the second dielectric layer, covering the phase change material layer.

In this embodiment, the metal silicide layer 320 functioning as the heating electrode is formed with a diameter smaller than that of the phase change material layer 324 and has a fixed diameter of about 10-90 nm. As shown in FIG. 4d, the heating electrode is formed with a rectangular cross section. The conductive semiconductor layer 302 and the conductive semiconductor layer 308a provide an n-p junction and thus functions as an active device for connecting the memory element.

According to above embodiment, the phase change memory device has the following advantages:

1. Because the phase change material layer is disposed directly over the active device therein, an area for disposing the unit memory cell can be reduced, thus, improving memory cell density.

2. Because a metal silicide layer 320 with a rectangular cross section is provided under the phase change material layer as the heating electrode, and a contact area therebetween is reduced.

3. In addition, because a metal silicide layer 320 with a rectangular cross section is provided under the phase change material layer as the heating electrode, write currents and reset currents can be further reduced, thus allowing for further reduction of the cell size.

4. According to illustrations in FIGS. 3a-3c, since the metal silicide layer 260 which functions as a heating electrode is formed with a rectangular cross section by a non-photolithographical method. Thus, adjustments and size reduction of the heating electrode will not be limited by the photolithography process as that mentioned in the conventional process.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A phase change memory device, comprising:
a semiconductor substrate;
a first conductive semiconductor layer disposed over the semiconductor substrate, wherein the first conductive semiconductor layer has a first conductivity type;
a first dielectric layer disposed over the semiconductor substrate, covering the first conductive semiconductor layer;
a second conductive semiconductor layer disposed in the first dielectric layer, and stacked over the first conductive semiconductor layer, wherein the second conductive semiconductor layer has a second conductivity type opposite to the first conductivity type;
a heating electrode disposed in the first dielectric layer and formed over the second conductive semiconductor layer, wherein the heating electrode has a tapered cross section and comprises metal silicide, and a top surface of the heating electrode is exposed by the first dielectric layer;
a second dielectric layer disposed over the first dielectric layer, covering the heating electrode;
a phase change material layer disposed in the second dielectric layer, covering the heating electrode; and
an electrode disposed over the second dielectric layer, covering the phase change material layer.

2. The phase change memory device as claimed in claim 1, wherein the first conductivity type is n type and the second conductivity type is p type.

3. The phase change memory device as claimed in claim 1, wherein the phase change material layer comprises chalcogenide materials.

4. The phase change memory device as claimed in claim 1, wherein the first conductive semiconductor layer comprises doped polysilicon or doped amorphous silicon.

5. The phase change memory device as claimed in claim 1, wherein the second conductive semiconductor layer comprises doped polysilicon or doped amorphous silicon.

6. The phase change memory device as claimed in claim 1, wherein the heating electrode has a non-fixed diameter of about 10-90 nm.

7. A phase change memory device, comprising:
a semiconductor substrate;
a first conductive semiconductor layer disposed over the semiconductor substrate, wherein the first conductive semiconductor layer has a first conductivity type;
a first dielectric layer disposed over the semiconductor substrate, covering the first conductive semiconductor layer;
a second conductive semiconductor layer disposed in the first dielectric layer and stacked over the first conductive semiconductor layer, wherein the second conductive semiconductor layer has a second conductivity type opposite to the first conductivity type;
a heating electrode disposed in the first dielectric layer and formed over the second conductive semiconductor layer, wherein the heating electrode has a rectangular cross section and comprises metal silicide, and a top surface of the heating electrode is exposed by the first dielectric layer;
a second dielectric layer disposed over the first dielectric layer, covering the heating electrode;
a phase change material layer disposed in the second dielectric layer, covering the heating electrode; and
an electrode disposed over the second dielectric layer, covering the phase change material layer.

8. The phase change memory device as claimed in claim 7, wherein the first conductivity type is n type and the second conductivity type is p type.

9. The phase change memory device as claimed in claim 7, further comprising a liner layer disposed between the heating electrode and the first dielectric layer.

10. The phase change memory device as claimed in claim 7, wherein the phase change material layer comprises chalcogenide materials.

11. The phase change memory device as claimed in claim 7, wherein the first conductive semiconductor layer comprises doped polysilicon or doped amorphous silicon.

12. The phase change memory device as claimed in claim 7, wherein the second conductive semiconductor layer comprises doped polysilicon or doped amorphous silicon.

13. The phase change memory device as claimed in claim 7, wherein the heating electrode has a fixed diameter of about 10-90 nm.

14. A method for fabricating a phase change memory device, comprising:
providing a semiconductor substrate;
forming a first conductive semiconductor layer over the semiconductor substrate, wherein the first conductive semiconductor layer has a first conductivity type;
forming a first dielectric layer, covering the semiconductor substrate and the first conductive semiconductor layer;
forming a second conductive semiconductor layer and a heating electrode in the first dielectric layer, wherein the second conductive semiconductor layer and the heating electrode are sequentially stacked over the first conductive semiconductor layer, and the second conductive semiconductor layer has a second conductivity type different from the first conductivity type, and the heating electrode comprises metal silicide;
forming a phase change material layer, covering the heating electrode and portions of the first dielectric layer adjacent to the heating electrode;
forming a second dielectric layer, covering the first dielectric layer and the heating electrode and surrounding the phase change material layer; and
forming an electrode over the second dielectric layer, covering the phase change material layer.

15. The method as claim in claim 14, wherein the heating electrode has a diameter small than that of the phase change material layer.

16. The method as claim in claim 14, wherein the heating electrode has a tapered shape cross section.

17. The method as claim in claim 14, wherein the heating electrode has a rectangular cross section.

18. The method as claim in claim 14, wherein the first conductivity type is n type and the second conductivity type is p type for the heating electrode.

19. The method as claim in claim 14, further comprising disposing a liner layer between the heating electrode and the first dielectric layer.

20. The method as claim in claim 14, wherein the phase change material layer comprises chalcogenide materials.

21. The method as claim in claim 14, wherein the first conductive semiconductor layer comprises doped polysilicon or doped amorphous silicon.

22. The method as claim in claim 14, wherein second conductive semiconductor layer comprises doped polysilicon or doped amorphous silicon.

23. The method as claim in claim 14, wherein the heating electrode has a non-fixed diameter of about 10-90 nm.

24. The method as claim in claim 14, wherein the heating electrode has a fixed diameter of about 10-90 nm.
